(19) United States
(12) Patent Application Publication
(10) Pub. No.: US 2025/0040095 A1
(43) Pub. Date: Jan. 30, 2025

(54) PHASE-CHANGE TEMPERATURE REGULATING SYSTEM AND ELECTRONIC COMPONENT TESTING APPARATUS AND METHOD

(71) Applicant: CHROMA ATE INC., Taoyuan City (TW)

(72) Inventors: Xin-Yi Wu, Taoyuan City (TW); Yu-Wei Chuang, Taoyuan City (TW); I-Ching Tsai, Taoyuan City (TW)

(73) Assignee: CHROMA ATE INC., Taoyuan City (TW)

(21) Appl. No.: 18/660,542

(22) Filed: May 10, 2024

(30) Foreign Application Priority Data
Jul. 24, 2023 (TW) 112127638

(51) Int. Cl. H05K 7/20; G01R 1/04

(52) U.S. Cl. CPC H05K 7/20381; G01R 1/0458; H05K 7/20327

(57) ABSTRACT

A phase-change temperature regulating system and an electronic device testing apparatus and method are described. In an embodiment, the system uses a temperature regulating fluid chamber containing a temperature regulating fluid to allow the temperature regulating fluid to cover at least a part of at least one surface of an electronic component. When a temperature of the electronic component reaches a boiling point of the temperature regulating fluid, the temperature regulating fluid becomes steam through a phase change to transfer heat energy outward from the electronic component, and condenses on an inner surface of the fluid chamber to further transfer heat energy of the steam to a temperature-regulating apparatus. The condensed temperature regulating fluid flows back to the temperature regulating fluid, thereby continuously circulating.

### CROSS-REFERENCE TO RELATED APPLICATION

This non-provisional application claims priority under 35 U.S.C. § 119 (a) to Patent Application No. 112127638 filed in Taiwan, R.O.C. on Jul. 24, 2023, the entire contents of which are hereby incorporated by reference.

### BACKGROUND

### Technical Field

The instant disclosure relates to a phase-change temperature regulating system and an electronic device testing apparatus and method, and in particular, to a temperature regulating system using fluid phase changes, and an electronic device testing apparatus and method equipped with the system.

### Related Art

Electronic components undergo functional or characteristic testing before delivery from a factory to ensure quality of the products. However, during the testing process, since the electronic components generate heat, most testing apparatus are equipped with temperature regulating measures for electronic components.

As shown in FIG. 1, FIG. 1 is a schematic diagram of a cross-sectional view of a conventional electronic component testing apparatus equipped with a temperature regulating means. A tested electronic component C is placed inside a chip holder S, and a pressing mechanism PM is used above the chip holder S to press against the electronic component C to ensure that the electronic component C can fully contact the probes inside the chip holder. Furthermore, in the prior art, the temperature regulating means is provided in the pressing mechanism PM, and it cools the electronic component C through heat conduction. However, since functions of the electronic component C become increasingly powerful, power consumption is getting increasingly high, and a temperature during the test is also greatly increased correspondingly. However, due to the increasingly powerful functions and higher power consumption of electronic components C, the temperature of electronic components C during testing is also correspondingly greatly increased, and the heat conduction cooling form of the conventional pressing mechanism PM contact is obviously unable to meet the testing requirements of high-power electronic components C.

In addition, the Heterogeneous Integration Design Architecture System (HIDAS) has become a mainstream of existing semiconductor packaging technologies. This technology mainly integrates a variety of different chips, such as a memory chip and a logic chip, optoelectronic and electronic components, etc., through packaging and 3D stacking technologies. However, this will also cause the surface height of the semiconductor package to be uneven, which directly leads to the pressing mechanism being unable to fully contact the entire surface of the semiconductor package, thereby affecting the heat dissipation efficiency.

### SUMMARY

In view of this, embodiments of the instant disclosure provide a phase-change temperature regulating system, method and an electronic device testing apparatus equipped with the system, which can use fluid to directly contact an electronic component, and control a temperature of the electronic component through a circulation process of two phase changes of the fluid, thereby effectively improving temperature regulating efficiency and significantly reducing energy consumption.

A phase-change temperature regulating system according to an embodiment of the instant disclosure includes a temperature-regulating apparatus, a temperature regulating fluid supply module, a temperature regulating fluid recycling module, and a controller. The temperature-regulating apparatus includes a temperature regulating fluid chamber covering at least a part of at least one surface of an electronic component. The controller electrically connects the temperature-regulating apparatus, the temperature regulating fluid supply module, and the temperature regulating fluid recycling module. The controller controls the temperature regulating fluid supply module to supply a temperature regulating fluid to the temperature regulating fluid chamber; in response to a temperature of the electronic component being greater than or equal to a boiling point of the temperature regulating fluid, the temperature regulating fluid evaporates in the temperature regulating fluid chamber and condenses on an inner surface of the temperature regulating fluid chamber; and the controller controls the temperature regulating fluid recycling module to recycle the temperature regulating fluid from the temperature regulating fluid chamber.

An electronic component detection method according to an embodiment of the instant disclosure includes the following steps: First, the temperature regulating fluid supply module provides a temperature regulating fluid to the temperature regulating fluid chamber, where the temperature regulating fluid chamber covers at least a part of at least one surface of an electronic component; second, the electronic component is tested; and finally, the temperature regulating fluid recycling module recycles the temperature regulating fluid from the temperature regulating fluid chamber. During the process of testing the electronic component, in response to a temperature of the electronic component being greater than or equal to a boiling point of the temperature regulating fluid, the temperature regulating fluid evaporates in the temperature regulating fluid chamber and condenses on an inner surface of the temperature regulating fluid chamber.

An electronic device testing apparatus according to an embodiment of the instant disclosure includes a test socket, a temperature-regulating apparatus, a temperature regulating fluid supply module, a temperature regulating fluid recycling module, and a controller; the test socket includes a chip slot suitable for accommodating an electronic component; a lower surface of the temperature-regulating apparatus includes a liquid containing cavity; and the controller electrically connects the test socket, the temperature-regulating apparatus, the temperature regulating fluid supply module, and the temperature regulating fluid recycling module. The controller controls the temperature-regulating apparatus to contact the electronic component, and the liquid containing cavity and an upper surface of the electronic component form a temperature regulating fluid chamber; the controller controls the temperature regulating fluid supply module to supply a temperature regulating fluid to the temperature regulating fluid chamber; in response to a temperature of the electronic component being greater than or equal to a boiling point of the temperature regulating fluid, the temperature regulating fluid evaporates in the temperature regulating fluid chamber and condenses on an inner surface of the temperature regulating fluid chamber; and the controller controls the temperature regulating fluid recycling module to recycle the temperature regulating fluid from the temperature regulating fluid chamber.

In conclusion, in some embodiments, a temperature regulating principle adopted by the phase-change temperature regulating system, method and the electronic component testing apparatus equipped with the system is to use the temperature regulating fluid to directly contact an electronic component to be temperature-controlled. When the temperature of the electronic component reaches the boiling point of the temperature regulating fluid, the temperature regulating fluid evaporates and transfers heat energy outward from the electronic component. Furthermore, the steam condenses on the inner surface of the temperature regulating fluid chamber to further transfer the steam heat energy to the temperature-regulating apparatus; and the condensed temperature regulating fluid flows back to the temperature regulating fluid, and so on. Accordingly, through the two phase changes of the temperature regulating fluid, the heat generated by the electronic component can be quickly and effectively transferred to the temperature-regulating apparatus, thereby achieving excellent heat transfer efficiency.

Moreover, since the temperature regulating fluid has strong penetrating properties, it can penetrate into the gaps between any chips. Therefore, even for electronic components in 2.5D or 3D packages, it can completely cover the uneven surface of the electronic components, thereby achieving comprehensive and complete temperature control, which can significantly improve the temperature regulating efficiency.

### BRIEF DESCRIPTION OF THE DRAWINGS

FIG. 1 is a schematic diagram of a cross-sectional view of a conventional electronic component testing apparatus equipped with a temperature regulating means;

FIG. 2 is a diagram of a system architecture of an embodiment of an electronic device testing apparatus of the instant disclosure;

FIG. 3 is a schematic diagram of an embodiment of the electronic component testing apparatus of the instant disclosure;

FIG. 4 is a schematic diagram of a cross-sectional view of a first embodiment of a test station of the instant disclosure;

FIG. 5 is a schematic diagram of a cross-sectional view of a second embodiment of the test station of the instant disclosure; and

FIG. 6 is a schematic diagram of a cross-sectional view of a third embodiment of the test station of the instant disclosure.

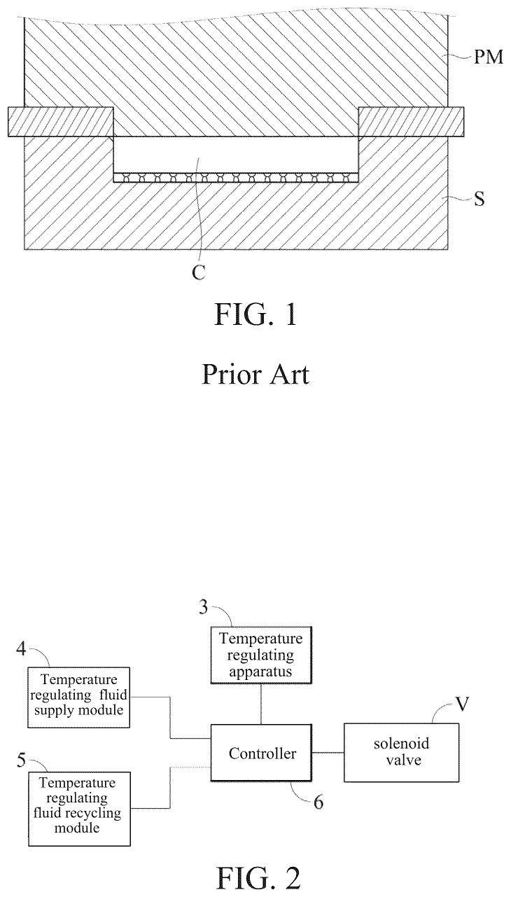

### DETAILED DESCRIPTION

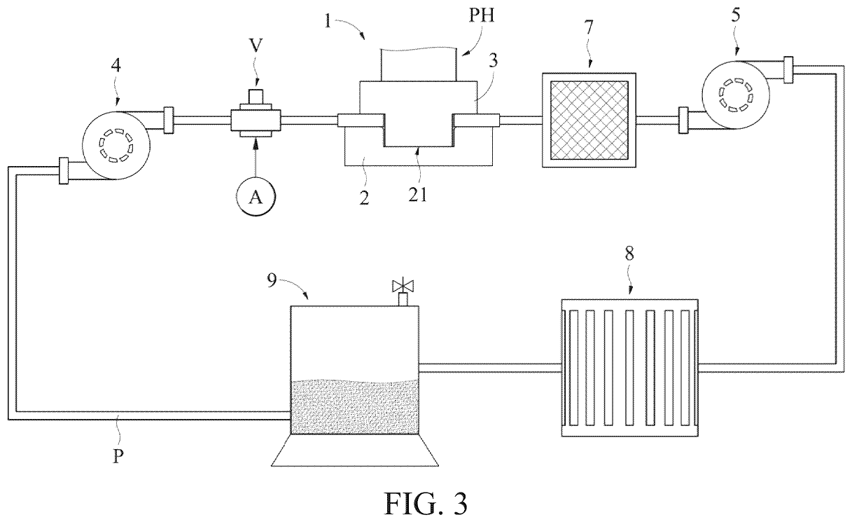

Referring to both FIG. 2 and FIG. 3, FIG. 2 is a diagram of a system architecture of an embodiment of an electronic device testing apparatus of the instant disclosure, and FIG. 3 is a schematic diagram of an embodiment of the electronic component testing apparatus of the instant disclosure. In an embodiment, a test socket 2, a temperature-regulating apparatus 3, a temperature regulating fluid supply module 4, a temperature regulating fluid recycling module 5, a controller 6, a filter 7, a heat exchanger 8, a storage tank 9, and an solenoid valve V may be included; and the controller 6 is electrically connected to the test socket 2, the temperature-regulating apparatus 3, the temperature regulating fluid supply module 4, the temperature regulating fluid recycling module 5, and the solenoid valve V, and controls the operations of these components.

Furthermore, the temperature regulating fluid supply module 4, the temperature regulating fluid recycling module 5, the filter 7, the heat exchanger 8, the storage tank 9, and the solenoid valve V form a closed fluid circulation loop with a test station 1 through a fluid line P, and the test station 1 includes the test socket 2 and the temperature-regulating apparatus 3. The temperature regulating fluid supply module 4 and the temperature regulating fluid recycling module 5 may each be a pump. The temperature regulating fluid supply module 4 is used to draw a temperature regulating fluid F from the storage tank 9 and pump the temperature regulating fluid F to the test station 1, and the temperature regulating fluid recycling module 5 draws the temperature regulating fluid F from the test station 1.

In other embodiments, the temperature regulating fluid supply module 4 is not limited to a pump, but can be any mechanism or apparatus that can supply the temperature regulating fluid F to the test station 1, for example, using gas pressure or gravity to deliver water. Similarly, in other embodiments, the temperature regulating fluid supply module 4 is not limited to a pump, and can be any mechanism or apparatus that can recycle the temperature regulating fluid F from the test station 1, for example, using gas pressure to drain water or using negative pressure to drain water.

The controller 6 is any single or multiple processor computing device or system capable of executing computer-readable instructions. Examples include, but are not limited to: workstations, laptops, client terminals, servers, distributed computing systems, handheld devices, or any other computing system or device. In its most basic configuration, the controller 6 may include at least one processor and system memory.

In an embodiment, an electronic engineering fluid with a low boiling point, such as 3M Fluorinert FC-72 (whose boiling point is 56° C.), 3M Novec Fluids 7000 (whose boiling point is 34° C.), or 3M Novec Fluids 7100 (whose boiling point is 61° C.) may be selected as the temperature regulating fluid F, but is not limited thereto. As long as it can achieve phase change within a lower temperature range (90° C.) and carry away a heat energy during the phase change process, any working fluid can be used in the instant disclosure.

The filter 7 is used to filter foreign objects such as impurities or dust in the temperature regulating fluid F. The heat exchanger 8 is used to exchange heat with the temperature regulating fluid F, for example, to lower the temperature of the temperature regulating fluid F. The storage tank 9 is used to store the temperature regulating fluid F. The solenoid valve V can be controlled to switch the test station 1 to be connected to the fluid line P or the atmosphere. A function of the solenoid valve V is that when the temperature regulating fluid supply module 4 supplies the temperature regulating fluid F to the test station 1, the solenoid valve V is controlled to switch the test station 1 to be connected to the fluid line P; and when the temperature regulating fluid recycling module 5 is to recycle the temperature regulating fluid F from the test station 1, the solenoid valve V is controlled to switch the test station 1 to be connected to the atmosphere A.

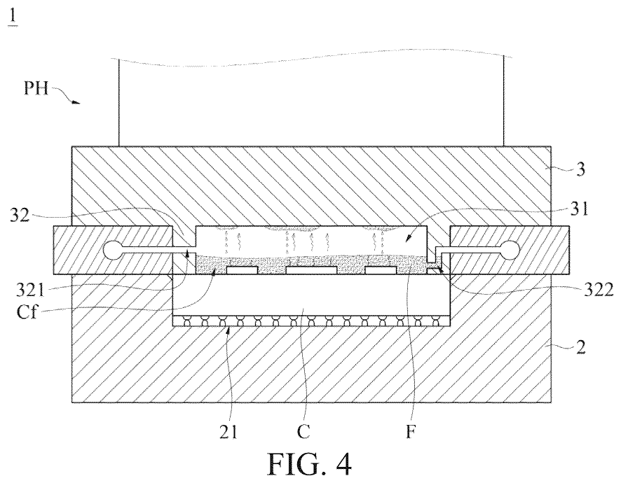

Referring to FIG. 4, FIG. 4 is a schematic diagram of a cross-sectional view of a first embodiment of the test station 1 of the instant disclosure. As shown in the figure, the test socket 2 includes a chip slot 21 suitable for accommodating an electronic component C and testing the electronic component C. The test socket 2 may be provided with a plurality of probes for electrically contacting contacts or tin balls on a bottom surface of the electronic component C.

The temperature-regulating apparatus 3 may be disposed in a workpress PH. The workpress PH may be controlled to move downward to press against the electronic component C on the test socket 2. The temperature-regulating apparatus 3 may be a high temperature generator or a low temperature generator, which may include but is not limited to a resistive heating element, a thermoelectric cooling module (TEC), or other devices that utilize the temperature regulating fluid F. In an embodiment, the temperature-regulating apparatus 3 can act as a condenser, for example, a circulating coolant passage inside the workpress PH, where the coolant may be liquid nitrogen, ethylene glycol, halogenated hydrocarbons, ammonia, sulfur dioxide, methane, or other cryogenic fluids.

Furthermore, in an embodiment, a lower surface of the temperature-regulating apparatus 3 includes a liquid containing cavity 31 with an opening facing the test socket 2, and the liquid containing cavity 31 and an upper surface of the electronic component C may form a temperature regulating fluid chamber Cf. To further explain, the lower surface of the temperature-regulating apparatus 3 includes an annular raised wall 32, and a liquid containing cavity 31 is formed on an inner side of the annular raised wall 32; a fluid inlet 321 and a fluid outlet 322 are provided on two corresponding sides of the annular raised wall 32.

The following describes the operation process of the first embodiment. First, the controller 6 controls the workpress PH to descend, and the annular raised wall 32 on the lower surface of the temperature-regulating apparatus 3 press down the electronic component C. In this case, the liquid containing cavity 31 and the upper surface of the electronic component C form the temperature regulating fluid chamber Cf. In other embodiments, a sealing component (not shown in the figure), such as an O-ring or a rubber gasket, may be attached to a lower surface of the annular raised wall 32, to ensure a sealing effect of the temperature regulating fluid chamber Cf.

Furthermore, the controller 6 controls the temperature regulating fluid supply module 4 to supply the temperature regulating fluid F to the temperature regulating fluid chamber Cf through the fluid inlet 321. When the temperature regulating fluid F reaches a specific amount, the supply may be stopped. For example, when it occupies 60% of a volume of the temperature regulating fluid chamber Cf, without the need to completely fill the entire temperature-controlled fluid cavity Cf.

Then, the controller 6 controls the test socket 2 to start testing the electronic component C. However, during the testing process, the electronic component C will generate heat. When a temperature of the electronic component C reaches a boiling point of the temperature regulating fluid F, the temperature regulating fluid F will evaporate in the temperature regulating fluid chamber Cf and rapidly expand in volume, thereby transferring heat energy outward from the temperature regulating fluid F itself, and the temperature regulating fluid F in a vapor phase will quickly fill the entire temperature regulating fluid chamber Cf. When the temperature regulating fluid F in the vapor phase contacts with a low temperature area, such as an inner surface of the temperature regulating fluid chamber Cf, especially an upper surface of the chamber, condensation will occur, and heat accumulated during evaporation will be released through the condensation phenomenon. The condensed temperature regulating fluid F in a liquid phase will be affected by gravity and will flow back to the underlying liquid temperature regulating fluid F. This operation will be repeated in the temperature regulating fluid chamber Cf.

When the test is completed, the solenoid valve V is controlled by the controller 6, and is switched the fluid inlet 321 to connect to the atmosphere A. The temperature regulating fluid recycling module 5 is controlled to be enabled, so that the temperature regulating fluid recycling module 5 starts to draw the temperature regulating fluid F, and then recycles the temperature regulating fluid F from the temperature regulating fluid chamber Cf through the fluid outlet 322. After completing the recycling of the temperature regulating fluid F, the controller 6 controls the workpress PH to rise, and at this time the next electronic component C can be replaced for testing.

As can be seen from the above descriptions, in the first embodiment, the temperature regulating fluid chamber Cf covers most of the upper surface of the electronic component C, so that the temperature of the electronic component C can be effectively controlled. This means that the temperature of the electronic component C can at least be roughly maintained near the boiling point of the temperature regulating fluid F. When the temperature regulating fluid F undergoes its first phase change, that is, the temperature regulating fluid F boils and evaporates from a liquid state to a vapor state, and heat can be taken away from the electronic component C. When the temperature regulating fluid F undergoes its second phase change, that is, the temperature regulating fluid F cools down and condenses from the vapor state to the liquid state, and heat in the steam can be transferred to the temperature-regulating apparatus 3. Accordingly, the temperature regulating fluid F can provide quite excellent heat conduction efficiency and heat dissipation efficiency during two phase changes.

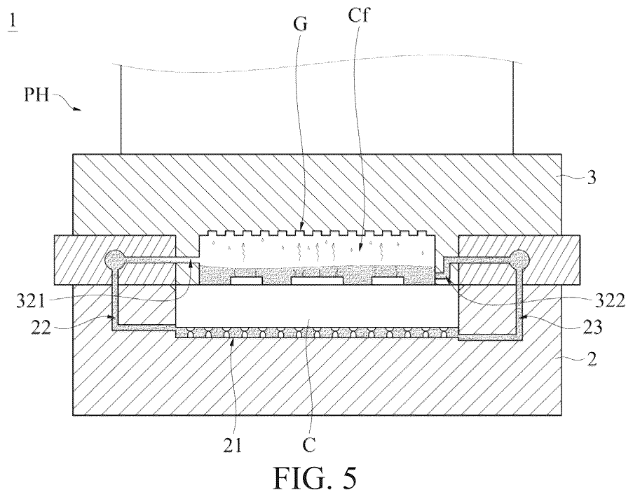

Referring to both FIG. 3 and FIG. 5, FIG. 5 is a schematic diagram of a cross-sectional view of a second embodiment of the test station of the instant disclosure. In the embodiment shown in the figure, the test socket 2 further includes a fluid inlet channel 22 and a fluid outlet channel 23. The fluid inlet channel 22 is coupled to communicate with the temperature regulating fluid supply module 4, and the fluid outlet channel 23 is coupled to communicate with the temperature regulating fluid recycling module 5. Furthermore, the fluid inlet channel 22 and the fluid outlet channel 23 may be disposed on two corresponding sides of a bottom of the chip slot 21, and the number may be one or more.

During the testing process, the controller 6 controls the temperature regulating

fluid supply module 4 to supply the temperature regulating fluid F to the chip slot 21 through the fluid inlet channel 22, and controls the temperature regulating fluid recycling module 5 to recycle the temperature regulating fluid F from the chip slot 21 through the fluid outlet channel 23. In other words, during the entire testing process, the temperature regulating fluid F circulates intermittently or continuously within the chip slot 21.

However, a specific technical means for allowing the temperature regulating fluid F to circulate within the chip slot 21 is to configure the fluid inlet channel 22 and the fluid inlet 321 as different fluid passages, and a solenoid valve (not shown in the figure) may be used to switch between the passages. To be specific, when the temperature regulating fluid chamber Cf is filled with a specific amount of the temperature regulating fluid F, the solenoid valve switches to connect the fluid inlet channel 22 to the temperature regulating fluid supply module 4. Similarly, the fluid outlet channel 23 and the temperature regulating fluid recycling module 5 may also be configured in the same manner. In addition, an inner top surface of the temperature regulating fluid chamber Cf is provided with a plurality of grooves G. A purpose thereof is not only to increase a heat exchange area and improve condensation efficiency, but also to accelerate the return rate of the condensed liquid.

Overall, in the second embodiment, a temperature of the upper surface of the electronic component C is still controlled by the phase change of the temperature regulating fluid F, which belongs to two-phase cooling; while a temperature of a lower surface of the electronic component C is controlled by the circulating temperature regulating fluid F, which belongs to single-phase cooling. Therefore, this embodiment can provide temperature regulating means for both the upper and lower surfaces of the electronic component C, thereby achieving an excellent temperature regulating effect. In addition, in other embodiments, the temperature regulating means provided on the lower surface of the electronic component C is not limited to the liquid temperature regulating fluid F, and may use other different fluids or gases, such as cryogenically regulated compressed air, nitrogen, or carbon dioxide.

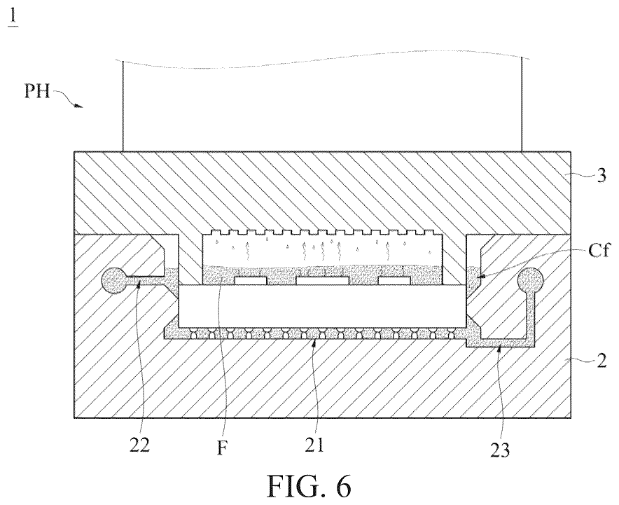

Referring to both FIG. 3 and FIG. 6, FIG. 6 is a schematic diagram of a cross-sectional view of a third embodiment of the test station 1 of the instant disclosure. In this embodiment, the temperature regulating fluid chamber Cf is formed by the chip slot 21 of the test socket 2 and the lower surface of the temperature-regulating apparatus 3. Therefore, before testing the electronic component C, since the electronic component C is entirely located in the temperature regulating fluid chamber Cf, when the controller 6 controls the temperature regulating fluid supply module 4 to supply the temperature regulating fluid F to the temperature regulating fluid chamber Cf through the fluid inlet channel 22, the electronic component C is completely immersed in the temperature regulating fluid F, so that comprehensive temperature regulating can be provided.

In conclusion, in a plurality of embodiments of the instant disclosure, in addition to using the temperature regulating fluid F for heat dissipation through a two-phase phase change on a single surface of the electronic component C, single-phase cooling can also be performed with the temperature regulating fluid F forced to flow on another surfaces of the electronic component C. In addition, the electronic component C may alternatively be completely immersed in the temperature regulating fluid F, and the temperature regulating fluid F directly and comprehensively contacts the electronic component C to conduct heat energy, thereby achieving an immersive temperature regulating effect.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A phase-change temperature regulating system, comprising:
a temperature-regulating apparatus, wherein the temperature-regulating apparatus comprises a temperature regulating fluid chamber, and the temperature regulating fluid chamber covers at least a part of at least one surface of an electronic component;
a temperature regulating fluid supply module;
a temperature regulating fluid recycling module;
a controller, electrically connecting the temperature-regulating apparatus, the temperature regulating fluid supply module, and the temperature regulating fluid recycling module, wherein
the controller controls the temperature regulating fluid supply module to supply a temperature regulating fluid to the temperature regulating fluid chamber; in response to a temperature of the electronic component being greater than or equal to a boiling point of the temperature regulating fluid, the temperature regulating fluid evaporates in the temperature regulating fluid chamber and condenses on an inner surface of the temperature regulating fluid chamber; and the controller controls the temperature regulating fluid recycling module to recycle the temperature regulating fluid from the temperature regulating fluid chamber.

2. The phase-change temperature regulating system according to claim 1, wherein a lower surface of the temperature-regulating apparatus comprises a liquid containing cavity, and the liquid containing cavity is suitable for forming the temperature regulating fluid chamber with an upper surface of the electronic component.

3. The phase-change temperature regulating system according to claim 2, wherein the lower surface of the temperature-regulating apparatus comprises an annular raised wall, and the liquid containing cavity is formed on an inner side of the annular raised wall; the annular raised wall comprises a fluid inlet and a fluid outlet; and the temperature regulating fluid supply module supplies the temperature regulating fluid to the temperature regulating fluid chamber through the fluid inlet, and the temperature regulating fluid recycling module draws the temperature regulating fluid from the temperature regulating fluid chamber through the fluid outlet.

4. An electronic component detection method, wherein the electronic component detection method comprises the following steps:
(A) providing, by a temperature regulating fluid supply module, a temperature regulating fluid to a temperature regulating fluid chamber, wherein the temperature regulating fluid chamber covers at least a part of at least one surface of an electronic component;
(B) testing the electronic component; and
(C) recycling, by a temperature regulating fluid recycling module, the temperature regulating fluid from the temperature regulating fluid chamber; wherein
in the step (B), in response to a temperature of the electronic component being greater than or equal to a boiling point of the temperature regulating fluid, the temperature regulating fluid evaporates in the temperature regulating fluid chamber and condensed on an inner surface of the temperature regulating fluid chamber.

5. The electronic component detection method according to claim 4, wherein in the step (A), a temperature-regulating apparatus contacts the electronic component, and the temperature-regulating apparatus comprises a liquid containing cavity that is suitable for forming the temperature regulating fluid chamber with at least one surface of the electronic component.

6. The electronic component detection method according to claim 5, wherein a lower surface of the temperature-regulating apparatus comprises a annular raised wall, and the liquid containing cavity is formed on an inner side of the annular raised wall; the annular raised wall comprises a fluid inlet and a fluid outlet; and the temperature regulating fluid supply module supplies the temperature regulating fluid to the temperature regulating fluid chamber through the fluid inlet, and the temperature regulating fluid recycling module draws the temperature regulating fluid from the temperature regulating fluid chamber through the fluid outlet.

7. The electronic component detection method according to claim 4, wherein in the step (A), the electronic component is entirely located in the temperature regulating fluid chamber.

8. An electronic device testing apparatus, comprising:
a test socket, wherein the test socket comprises a chip slot suitable for accommodating an electronic component;
a temperature-regulating apparatus, wherein a lower surface of the temperature-regulating apparatus comprises a liquid containing cavity;
a temperature regulating fluid supply module;
a temperature regulating fluid recycling module; and
a controller electrically connecting the test socket, the temperature-regulating apparatus, the temperature regulating fluid supply module and the temperature regulating fluid recycling module, wherein
the controller controls the temperature-regulating apparatus to contact the electronic component, the liquid containing cavity and an upper surface of the electronic component form a temperature regulating fluid chamber; the controller controls the temperature regulating fluid supply module to supply a temperature regulating fluid to the temperature regulating fluid chamber; in response to a temperature of the electronic component being greater than or equal to a boiling point of the temperature regulating fluid, the temperature regulating fluid evaporates in the temperature regulating fluid chamber and condenses on an inner surface of the temperature regulating fluid chamber; and the controller controls the temperature regulating fluid recycling module to recycle the temperature regulating fluid from the temperature regulating fluid chamber.

9. The electronic component testing apparatus according to claim 8, wherein the test socket further comprises a fluid inlet channel and a fluid outlet channel; and the controller controls the temperature regulating fluid supply module to supply the temperature regulating fluid to the chip slot through the fluid inlet channel, and controls the temperature regulating fluid recycling module to recycle the temperature regulating fluid from the chip slot through the fluid outlet channel.

10. The electronic component testing apparatus according to claim 8, wherein the lower surface of the temperature-regulating apparatus comprises a annular raised wall, and the liquid containing cavity is formed on an inner side of the annular raised wall; the annular raised wall comprises a fluid inlet and a fluid outlet; and the temperature regulating fluid supply module supplies the temperature regulating fluid to the temperature regulating fluid chamber through the fluid inlet, and the temperature regulating fluid recycling module draws the temperature regulating fluid from the temperature regulating fluid chamber through the fluid outlet.
